(19) United States
(12) Patent Application Publication
(10) Pub. No.: US 2013/0330474 A1
(43) Pub. Date: Dec. 12, 2013

(54) Apparatus for Coating a Substrate

(71) Applicants: Andreas Caspari, St. Wendel (DE); Emmerich Manfred Novak, Kloster Lehnin (DE)

(72) Inventors: Andreas Caspari, St. Wendel (DE); Emmerich Manfred Novak, Kloster Lehnin (DE)

(21) Appl. No.: 13/990,704

(22) PCT Filed: Nov. 30, 2011
(86) PCT No.: PCT/EP2011/005997

§ 371 Date: Aug. 23, 2013

(30) Foreign Application Priority Data
Nov. 30, 2010 (DE) 10 2010 052 761.0

(51) Int. Cl. C23C 16/458

(52) U.S. Cl. CPC C23C 16/458
USPC 427/255.5; 118/729

(57) ABSTRACT

The invention relates to an apparatus (1) for coating a surface (21) of a substrate (20) which during the coating process is accommodated in a processing chamber (2) and is exposed to a stream of coating particles (23) produced by a particle source (4). A transport device (10) is provided for transport of the substrate (20) through the processing chamber (2). To avoid deposits of the coating material on sensitive components of the transport device (10), the transport device (10) is arranged in the processing chamber (2) in such a way that it is screened from the particle stream emanating from the particle source (4) by the substrate (20) to be transported. In this way, the intervals between maintenance can be extended and the operating costs of the apparatus (1) can be reduced. The invention further relates to a process for coating a surface (21) of a substrate (20) in an apparatus (1) having a processing chamber (2) for accommodating the substrate (20) during the coating process, having a particle source (4) for producing coating particles (23) and having a transport device (10) for transport of the substrate (20) in the processing chamber (2) which has a plurality of transport rollers (11a) which are fastened to a set of shafts (11b) which are mounted in bearings (11c) so as to be rotatable, are arranged behind one another in the transport direction (13) and are aligned parallel to one another, where the transport device (10) or at least one of the transport rollers (11a), one of the shafts (11b) or one of the bearings (11c) of the transport device (10) is screened from a stream of coating particles (23) emanating from the particle source (4) by the substrate (20) to be transported or by two substrates (20) to be transported in succession.

The invention relates to an apparatus for coating a surface of a substrate according to the precharacterizing clause of claim 1.

In the production of liquid-crystal displays and thin-film solar cells, there is often a need to apply transparent conducting oxide layers (TCOs—transparent conducting oxides) onto a transparent substrate, in particular a glass or a film. These TCOs combine two important properties: electrical conductivity and optical transparency. They can—depending on the chemical composition—be deposited on the substrate with the aid of DC/RF magnetron sputtering, reactive MF magnetron sputtering or CVD (chemical vapor deposition). Examples of TCO materials are In₂O₃:SnO₂ (ITO), ZnO:Al or SNO₂:F.

For coating a substrate with a TCO with the aid of cathode sputtering, or sputtering technology, a plurality of solid sources (targets) are typically arranged in an elongate processing chamber under vacuum, or in a protective gas atmosphere, and are bombarded with high-energy ions so that the desired coating material is generated in the form of a particle vapor or gas. This coating material is deposited on the surface of the substrate, which moves slowly through the processing chamber. For transporting the substrate, a continuous conveyor apparatus is used, which comprises transport rolls that are driven with the aid of a drive motor.

During the coating process, the coating material is not only applied onto the substrate, but also some of the coating material reaches the walls of the coating chamber and other surfaces located in the coating chamber, where they form undesired but unavoidable deposits. During prolonged operation, thick layers are thus formed, which can become detached and lead to contamination of the substrate. In order to counteract this problem, the walls of the coating chamber could be provided with a shielding grid which is arranged at a distance from one in the inner wall of the coating chamber. Deposits which form on the inner wall are trapped in the cavity between the inner wall of the coating chamber and the shielding grid; they therefore cannot reach the substrate to be coated and damage it

Besides the problem of substrate contamination due to layers detached from the inner walls of the processing chamber, the deposits cause damage to movable, sensitive components of the conveyor apparatus which interact with one another (for example the transport roll bearings and force transmission components), which leads to short maintenance intervals and therefore high operating costs of the coating system.

It is therefore an object of the invention to improve the coating of substrate surfaces in such a way that the maintenance outlay which is entailed by operationally induced contaminations and deposits in the coating apparatus can be reduced. In particular, the conveyor apparatus used for transporting the substrate in the processing chamber is intended to be made less sensitive to the flow of coating particles.

The object is achieved by the features of the independent claims. Advantageous configurations are the subject-matter of the dependent claims.

Accordingly, the conveyor apparatus is configured, and arranged in the processing chamber, in such a way that the components of the conveyor apparatus are protected against the flow of coating particles, which are emitted. by the particle source, directly by the flat substrate which is being transported by the conveyor apparatus. Furthermore, the components of the conveyor apparatus may be shielded even more comprehensively from a flow of coating particles emitted by the particle source by two substrates to be transported successively, if only a narrow gap is then adjusted between the substrates only if required.

The conveyor apparatus is thus so to speak “in the shadow” of the substrate or substrates. In this way, the substrate shields a large part of the particle flow emitted by the particle source, which therefore cannot reach the sensitive components of the conveyor apparatus. The degree of contamination of the conveyor apparatus is therefore greatly reduced, so that less maintenance outlay is necessary.

A particularly comprehensive shielding effect can be achieved when at least two of the shafts are arranged relative to the particle source in such a way that the flow of coating particles emitted by the particle source is directed into the spatial region lying between the shafts, since the flow density in the region of the shafts is then substantially less than in the region between the shafts.

In addition to the shielding of the conveyor apparatus by the substrate, it is advantageous to provide a further shielding apparatus which protects the bearing and drive components of the conveyor apparatus against deposits due to an indirect particle flow (that is to say scattered or reflected coating particles). This shielding apparatus expediently comprises a plurality of metal shielding plates, which are arranged in immediate proximity to the shafts, the drive chain, the drive gearwheels and/or the bearings of the conveyor. apparatus. These metal shielding plates prevent coating particles, which are emitted or scattered past the substrate in the region of the conveyor apparatus, from being able to reach the sensitive components of the conveyor apparatus and be deposited there.

The metal shielding plates are advantageously roughened by blasting, so that coating particles deposited there form a well-adhering coating; in this way, detachment of the deposits and the concomitant risk of substrate contamination are reduced.

It is furthermore advantageous to provide an extensive shielding grid on the metal shielding plates—as well as on other selected surfaces in the interior of the processing chamber—which is arranged in front of the metal shielding plate in such a way that the coating material in gas or vapor form generated by the particle source can pass through the openings of the shielding grid onto the metal shielding plate surface lying behind and can be deposited there. The openings of the shielding grid are dimensioned in such a way that detached deposits cannot escape through the shielding grid, but are trapped in a free space between the shielding grid and the associated surface of the metal shielding plate, and can be removed therefrom in a controlled way. In this way, detached deposits are reliably kept away from the substrate to be coated, so that contaminations of the substrate surface are effectively prevented.

In order to configure the protective apparatus as compactly as possible, the shielding grid expediently extends approximately parallel to and at a short distance from the surface to be shielded, and the height of the free space formed between the shielding grid and the metal shielding plate is typically between 2 and 10 mm, preferably about 5 mm. In order to ensure a stable structure, the shielding grid is advantageously fastened on the associated surface with the aid of spacers. The shielding grid may, in particular, consist of an expanded metal. As is known, expanded metal is an extensive material having openings in the surface, which are generated by offset cuts with simultaneous stretching deformation of a plate. The openings are dimensioned in such a way that, on the one hand, the particles in gaseous or vapor form can pass through the expanded metal onto the wall lying behind, but on the other hand the deposits possibly detached, from the wall can no longer pass back into the coating region.

Advantageously, the processing chamber is configured in such a way that it is suitable for both cold and hot processing of the substrates. It is then expedient to provide the transport rolls of the conveyor apparatus with a thermal insulation layer at least in sections. The conveyor apparatus is therefore heat-resistant in the region of the hot zone, and therefore capable of conveying cold and hot substrates through the processing chamber without additional carriers or the like.

The method according to the invention for coating a surface of a substrate in an apparatus
having a processing chamber for receiving the substrate 20) during the coating process,
having a particle source for generating coating particles,
and having a conveyor apparatus for transporting the substrate in the processing chamber, which comprises a multiplicity of transport rolls that are fastened on a set of shafts which are rotatably mounted in bearings, are arranged successively in the forward displacement direction and are aligned mutually parallel, characterized in that the conveyor apparatus or at least one of the transport rolls, one of the shafts or one of the bearings of the conveyor apparatus is shielded by the substrate to be transported, or by two substrates to be transported successively, against a flow of coating particles emitted by the particle source.

The method has advantages corresponding to the apparatus.

The invention will be explained in more detail below with the aid of an exemplary embodiment represented in the figures, in which:

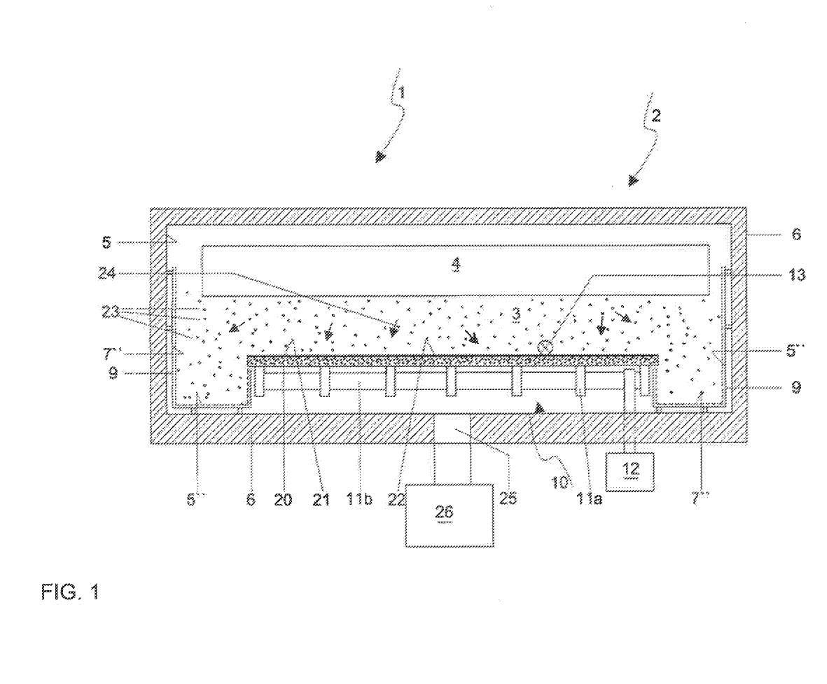

FIG. 1 shows a schematic sectional view through an apparatus for substrate coating having a conveyor apparatus according to the invention, the section plane being perpendicular to the conveying direction;

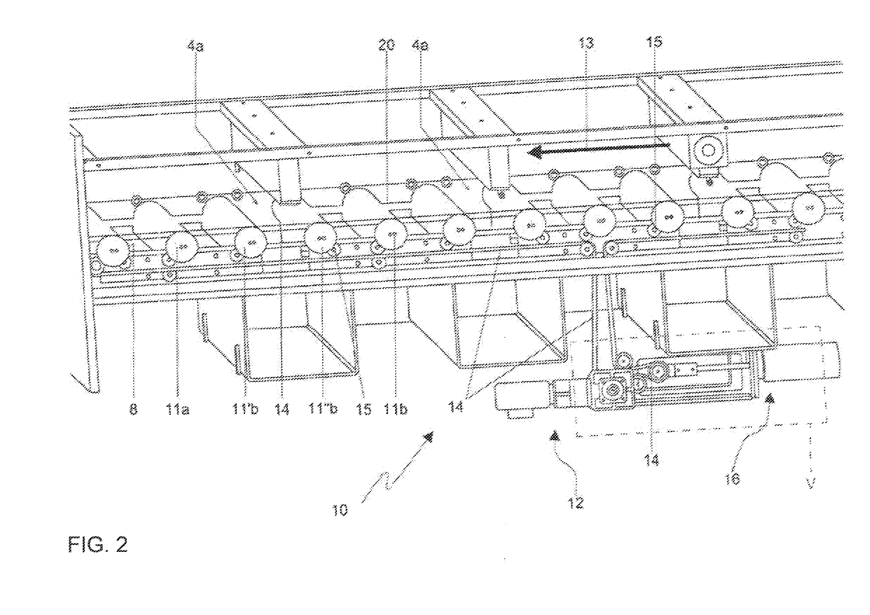

FIG. 2 shows a perspective sectional view of the conveyor apparatus of FIG. 1, the section Plane being parallel to the conveying direction;

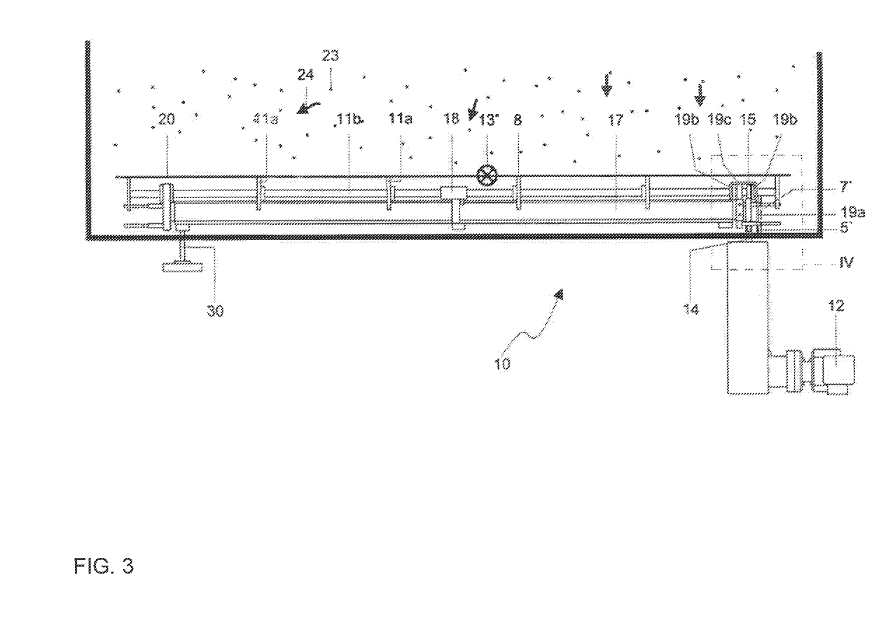

FIG. 3 shows a view of the conveyor apparatus of FIG. 2, with a viewing direction parallel to the conveying direction;

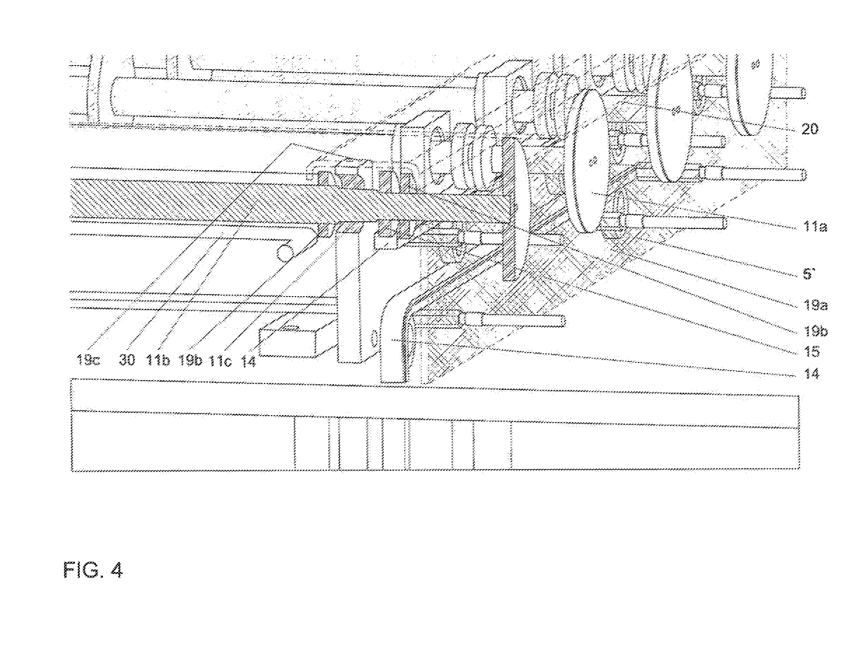

FIG. 4 shows a perspective detail view of the force transmission system of the conveyor apparatus according to detail IV in FIG. 3;

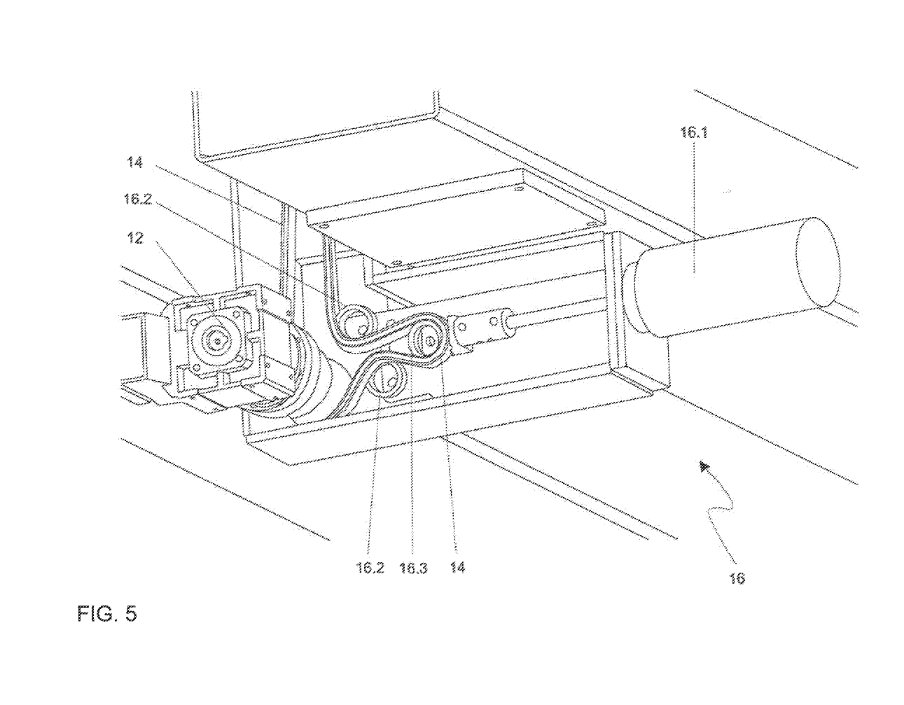

FIG. 5 shows a perspective sectional view of a chain tensioner for adjusting the tension of a drive chain in a conveyor apparatus according to detail V in FIG. 2.

In the drawings, elements which correspond to one another are denoted by the same references. The drawings represent a schematic exemplary embodiment and do not reflect specific parameters of the invention. Furthermore, the drawings merely serve to explain an advantageous embodiment of the invention and are not to be interpreted in such a way that they restrict the protective scope of the invention.

FIG. 1 shows a schematic sectional view of an apparatus 1 for coating a surface 21 of a substrate 20 with the aid of a sputtering process. The coating apparatus 1 comprises a processing chamber 2, in the interior 3 of which one or more particle sources 4 for generating the coating particles 23 in vapor form used for the coating are arranged. The vapor particles 23 may, for example, be generated by chemical vapor deposition (CVD), with a plurality of gaseous starting substances reacting with one another in order to form the particles 23 with the desired chemical composition. The vapor particles 23 may furthermore be generated by physical vapor deposition methods (PVD). In this case, into the vapor particles 23 are ejected from a target consisting of the coating material with the aid of laser beams, magnetically deflected ions or electrons, by arc discharge etc., move through the interior 3 of the processing chamber 2 and are deposited on the substrate 20 and/or on other surfaces 5, 5″ in the interior of the processing chamber 2, where the layer formation takes place. The coating process is carried out in a vacuum, for which reason connections 25 for vacuum pumps 26 are provided in the wall 6 of the processing chamber 2.

The substrate 20 is a large-format flat glass substrate, which is provided in the coating apparatus 1 with a TCO (transparent conducting oxide) coating 22 for solar applications. To this end, the substrate 20 is moved with the aid of a conveyor apparatus 10 in a forward displacement direction 13 through the flow of coating particles 23 in vapor form generated by the particle source 4, the surface 21 of the substrate 20 facing toward the particle source 4 being coated, The forward displacement direction 13 of the conveyor apparatus 10 is arranged perpendicularly to the plane of the drawing in the sectional view of FIG. 1.

FIG. 2 shows a detail representation of the conveyor apparatus 10 of FIG. 1 in a perspective sectional representation, in which the forward displacement direction 13 is arranged parallel to the plane of the drawing and is indicated by an arrow. The conveyor apparatus 10 comprises a multiplicity of transport rolls 11a which—as can be seen in the perspective representation of FIG. 2 and in the front view of FIG. 3—are fastened on a set of rotatably mounted shafts 11b arranged successively in the forward displacement direction 13 and aligned mutually parallel. Gearwheels 15, by means of which the shafts 11b are coupled with the aid of a drive chain 14 to a drive motor 12, are furthermore fastened on the shafts 11b. The drive chain 14 bears sequentially on all the shafts 11b and therefore drives all the shafts 11b together and synchronously. This leads to a synchronized rotational movement of the shafts 11b (and therefore of the transport rolls 11a), so that the substrate 20 is moved uniformly through the processing chamber 3. The transport rolls 11a are provided in sections with a thermal insulation layer 8, for example consisting of a ceramic, by which the substrate 20 moved on the conveyor apparatus 10 is thermally insulated from the conveyor apparatus 10.

A chain tensioner 16, with the aid of which the tension of the drive chain 14 can be adjusted, is arranged next to the drive motor 12. A perspective detail representation of the chain tensioner 16 is shown in FIG. 5: the chain tensioner 16 comprises two stationary gearwheels 16.2 and a movably mounted gearwheel 16.3, which can be displaced relative to the other two gearwheels 16.2 by actuating a tension cylinder 16.1. Actuation of the tension cylinder 16.1 therefore leads to an. increase or decrease in the tension in the drive chain 14 fed between the gearwheels 16.1 and 16.2.

During the coating process—besides the (desired) particle deposition on the substrate surface 21—the vapor particles 23 generated in the particle source 4 are also deposited at other positions in the interior of the processing chamber 2, for example on the inner walls 5.

In order to protect the conveyor apparatus 10, in particular its drive system, from deposits, the conveyor apparatus 10 is configured, and arranged in the processing chamber 2, in such a way that the entire drive system is shielded by the substrate 20 to be transported against the vapor particle flow 24 arriving from above: the transport rolls 11a, the shafts 11b and their bearings 11c as well as support rolls 18, a drive support system 17 and the force transmission system 14, 15, as can be seen from the sectional representation of FIG. 3, are arranged entirely below the substrate 20 so that at least these components of the conveyor apparatus 10 are shielded by the substrate 20 against the flow of coating particles 23 emitted by the particle source 4,

Furthermore, at least two of the shafts 11b are arranged relative to the particle source 4 in such a way that the flow of coating particles 23 emitted by the particle source 4 is directed into the spatial region 4a lying between the shafts, for example the shafts 11′b, 11″b, a region of high flow density being arranged between the regions in which the shafts 11b lie, while lower flow densities occur in the regions in which the shafts 11b are arranged. In one embodiment, the particle source 4 lies above the shafts 11b and emits the coating particles primarily into a region perpendicularly downward. The shafts 11b are laterally offset with respect to the regions with a high flow density of the coating particles. Particularly comprehensive shielding is achieved when two substrates to be transported successively have only a short distance from one another during the transport, i.e. when two substrates are transported at only a short distance from one another. In this case, only a narrow gap through which coating particles can pass remains between the substrates.

The drive motor 12 lies outside the processing chamber 2. The parts of a cooling system 30 which are located inside the processing chamber 2 are also routed below the substrate 20 to be transported, and are therefore shielded by the substrate 20 against the vapor particles 23 flowing in from above.

In addition to this shielding by the substrate 20, in order to protect the sensitive bearing and drive components of the conveyor apparatus 10, a shielding apparatus 19 comprising metal shielding plates 19a, 19b, 19c is provided, which prevents or at least reduces the entry of vapor particles 23 into the region of the bearings 11b, of the gearwheels 15 and of the drive chain 14 (in this regard, see the detail representation of FIG. 4): a lateral metal shielding plate 19a applied laterally on the transport shafts 11b protects the drive chain 14 from a laterally entering particle flow. Disk-shaped metal bearing-protection plates 19b, which are provided on the transport shafts 11b in the region of the drive gearwheels 15 fastened on the transport shafts and of the shaft bearings 11c, shield these bearings 11c and the gearwheels 15 against entry of coating material 23. Furthermore, a cover rail 19c arranged above the shaft bearings 11c and the force transmission system 14, 15 ensures that vapor particles 23 also cannot reach the region of the bearings 11c, gearwheels 15 and drive chain 14 from above. The cover rail 19c may also extend parallel to the shaft bearings 11c over the length of the shaft bearings 11c.

The shielding apparatus 19 therefore reduces or prevents buildup of deposits in these regions, so that the repair and maintenance outlay to be expended for the conveyor apparatus 10 can be greatly reduced.

The shielding apparatus 19 is arranged in immediate proximity to the components 11c, 14, 15 to be protected and at the greatest possible distance from the particle source 4, so that the coating rate in the region of the shielding apparatus 19 is as low as possible. Nevertheless, the outer wall 5′ of the shielding apparatus 19, which faces the interior 3 of the processing chamber 2, is exposed to an (albeit reduced) flow of vapor particles 23, for which reason deposits of coating material are formed in these wall regions 5′ during operation—likewise as on the inner walls 5 of the processing chamber 2 or on the walls 5″, facing toward the particle source 4, of further protective metal plates 9 provided in the processing chamber 2. During continued operation. of the coating apparatus 1, these deposits reach a large layer thickness and become detached in the form of fragments. In order to reduce such detachment, the surfaces exposed to the particle vapor may be pretreated with the aid of special methods (for example roughening by blasting, plasma coating), which leads to improved adhesion of the deposited coating materials and reduces the risk of detachment of the deposited layer.

The fragments typically have the shape of flat platelets, but may also be in the form of compact grains or lumps, In order to prevent these fragments from reaching the substrate 20 and causing contamination of the substrate 20 and/or of the applied coating 22, the outer wall 5′ of the lateral metal shielding plate 19a is provided with a shielding grid 7′ (see FIG. 3). The shielding grid 7′ extends approximately parallel to the metal shielding plate 19a and is fastened thereon with the aid of spacers, so that a cavity having a width of between 2 and 10 mm is formed between the shielding grid 7′ and the outer wall 5′ of the metal shielding plate 19a. Furthermore, the walls 5″ of further protective metal plates 9 placed in the processing chamber 2 are also provided with shielding grids 7″ (see FIG. 1).

The shielding grid 7′, 7″ consists of an expanded metal. Expanded metal is an extensive material consisting of a metal plate or a plastic having openings, which are generated by offset cuts and stretching deformation of a starting plate. For use as a shielding grid 7, the expanded metal preferably consists of a thin steel plate or a metal plate of nonferrous material. The expanded metal, may be surface-treated and/or provided with a surface coating.

As can be seen from the above, according to the invention the conveyor apparatus 10, or at least one of the transport rolls 11a, one of the shafts 11b or one of the bearings 11c of the conveyor apparatus 10, is shielded by the substrate 20 to be transported, or by two substrates 20 to be transported successively, against the flow of coating particles 23 emitted by the particle source 4.

1.-11. (canceled)

12. An apparatus for coating a surface of a substrate, comprising:
a processing chamber for receiving the substrate during the coating process;
a particle source for generating coating particles;
a conveyor apparatus for transporting the substrate in the processing chamber, the conveyor apparatus comprising a plurality of transport rolls fastened on a set of shafts which are rotatably mounted in bearings, the transport rolls being arranged successively in a forward displacement direction and aligned parallel to one another, the shafts being coupled to a drive motor by means of drive gearwheels and a drive chain; and
a shielding apparatus comprising metal shielding plates arranged in the processing chamber for protecting bearings, drive gearwheels and drive chain against deposition of coating particles;
wherein the drive gearwheels and the drive chain are arranged below the substrate to be transported such that they are shielded by the substrate to be transported, or by two substrates to be transported successively, against a flow of coating particles emitted by the particle source.

13. The apparatus according to claim 12, further comprising a shielding grid arranged between the particle source and a surface, facing an interior of the shielding apparatus.

14. The apparatus according to claim 13, wherein the shielding grid is arranged approximately parallel to and at a distance from the surface, the distance between the shielding grid and the surface being between 2 and 10 mm.

15. The apparatus according to claim 14, wherein the shielding grid comprises an expanded metal.

16. The apparatus according to claims 12, wherein the transport rolls of the conveyor apparatus are provided with one or more sections of a thermal insulation layer.

17. The apparatus according to claim 12, wherein at least two of the shafts are arranged relative to the particle source such that the flow of coating particles emitted by the particle source is directed into the spatial region lying between the shafts.

18. A method for coating a surface of a substrate in a coating apparatus, comprising:
providing a processing chamber for receiving the substrate during the coating process;
providing a conveyor apparatus for transporting the substrate in the processing chamber, the conveyor apparatus comprising a plurality of transport rolls fastened on a set of shafts which are rotatably mounted in bearings, the transport rolls being arranged successively in a forward displacement direction and aligned parallel to one another, the shafts being coupled to a drive motor by means of drive gearwheels and a drive chain;
providing a shielding apparatus comprising metal shielding plates arranged in the processing chamber for protecting bearings, drive gearwheels and drive chain against deposition of coating particles;
arranging the drive gearwheels and the drive chain below the substrate to be transported such that they are shielded by the substrate to be transported, or by two substrates to be transported successively, against a flow of coating particles emitted by the particle source.
